(19) United States
(12) Patent Application Publication
(10) Pub. No.: US 2014/0076393 A1
(43) Pub. Date: Mar. 20, 2014

(54) FLEXIBLE SOLAR CELL AND MANUFACTURING METHOD THEREOF

(71) Applicant: INDUSTRIAL TECHNOLOGY RESEARCH INSTITUTE, Hsinchu (TW)

(72) Inventors: Yi-Ming Chang, Hsinchu City (TW); Chao-Feng Sung, Hsinchu City (TW); Mei-Ju Lee, Kaohsiung City (TW); Chia-Sheng Huang, Yilan County (TW); Chi-Yi Leu, Hsinchu City (TW)

(73) Assignee: INDUSTRIAL TECHNOLOGY RESEARCH INSTITUTE, Hsinchu (TW)

(21) Appl. No.: 13/677,316

(22) Filed: Nov. 15, 2012

(30) Foreign Application Priority Data
Sep. 17, 2012 (TW) 101134023

(51) Int. Cl. H01L 31/0224; H01L 31/18

(52) U.S. Cl. CPC H01L 31/022425; H01L 31/022466; H01L 31/1884
USPC 136/256; 438/67

(57) ABSTRACT

A flexible solar cell and a manufacturing method thereof are provided. The flexible solar cell includes a rigid transparent substrate, a transparent electrode, a photoactive layer, a metal electrode, an encapsulating structure and a flexible substrate. The transparent electrode is disposed on the rigid transparent substrate, the photoactive layer is disposed on the transparent electrode, and the metal electrode is disposed on the photoactive layer. The transparent electrode, the photoactive layer and the metal electrode are sealed by the encapsulating structure disposed on the rigid transparent substrate. The flexible substrate opposite to the rigid transparent substrate is disposed on the encapsulating structure.

### CROSS-REFERENCE TO RELATED APPLICATION

This application claims the priority benefit of Taiwan application serial no. 101134023, filed on Sep. 17, 2012. The entirety of the above-mentioned patent application is hereby incorporated by reference herein and made a part of this specification.

### TECHNICAL FIELD

The disclosure relates to a flexible solar cell and a manufacturing method thereof.

### BACKGROUND

In general, a flexible solar cell is required a flexible thin film as a substrate, and devices are then manufactured on the flexible thin film to achieve bending. However, when the flexible substrate is bent, the layered devices on the flexible substrate such as the indium tin oxide (ITO) transparent electrode, the photoactive layer or the metal electrode, may be peeled from each other or damaged, so that the deterioration is occurred, thereby affecting the reliability of the flexible solar cell.

In addition, the solar cell manufacture needs to rely on the module designed in series and/or parallel connections, so as to achieve a particular output of voltage current and meet the power output requirement in usage. The ITO electrode is generally utilized in current solar cell modules to connect with the metal electrode, so as to perform the series-parallel connection. However, because the sheet resistance of ITO electrode is higher than that of metal electrode, it may reduce the efficiency of the devices in the solar cell.

In view of mass production, the yield and quality of products are also key factors. After large area devices are manufactured, the control factors such as the current collection efficiency of the transparent electrode, the uniformity of the photoactive thin film and other fabrication parameters, are all closely related to the final device efficiency. In terms of device design, utilizing the structure design to achieve optimal quality and reducing the efficiency losses between the small-area device and the large-area module have become the focusing topics for person having ordinary skill in the art.

The solar cell modules may be categorized into two types, which are the monolithic type and the strip type, respectively. The monolithic type, as the name implies, is the structure of integrally formed. At present, it is the most common approach for silicon solar cells. It is capable of being fabricated in a single sheet and detected one-by-one precisely. However, under the circumstances of large area and the need for using the ITO transparent electrode, the high resistance of ITO may cause the device efficiency to loss substantially, resulting in fill factor (F.F.) decay of devices. Therefore, a metal busbar having a geometric shape (such as a honeycomb shape) may generally be disposed on the ITO transparent electrode for assisting the current collection and the transmission. Nevertheless, the more the manufacturing steps added, the more complicated the manufacturing process became, such that the manufacturing cost may be increased.

The strip-type solar cell module is another design approach commonly used for modules. It is mainly constituted by stripe patterns and directly performed the series-parallel connection on a single substrate. Such design has been commonly applied to the organic solar cell module and the copper indium gallium selenide (CIGS) solar cell module, where the manufacturing process is simple and a sub-module structure may be directly formed concurrently, and thus it is no need to be further assembled and the manufacturing cost is reduced. Nevertheless, the spacing between stripes and the alignment accuracy of such module need to be investigated, meanwhile, the required space for the devices connected in series needs to be sacrificed with regard to the area utilization rate.

### SUMMARY

One of exemplary embodiments comprises a flexible solar cell including a rigid transparent substrate, a transparent electrode, a photoactive layer, a metal electrode, an encapsulating structure and a flexible substrate. The transparent electrode is disposed on the rigid transparent substrate, the photoactive layer is disposed on the transparent electrode, and the metal electrode is deposed on the photoactive layer. The encapsulating structure seals the transparent electrode, the photoactive layer and the metal electrode on the rigid transparent substrate. The flexible substrate opposite to the rigid transparent substrate is disposed on the encapsulating structure.

Another of exemplary embodiments comprises a manufacturing method of a flexible solar cell, and the manufacturing method includes the following steps. Firstly, a rigid transparent substrate is provided. Subsequently, a plurality of transparent electrodes is formed on the rigid transparent substrate. Thereafter, a photoactive layer is formed on each of the transparent electrodes. Afterwards, a metal electrode is formed on each of the photoactive layers, so as to form a plurality of solar cells constituted by each of the transparent electrodes, the photoactive layers and the metal electrodes. Subsequently, a plurality of encapsulating structures is formed on the rigid transparent substrate, wherein each of the solar cells is sealed by each of the encapsulating structures. Afterwards, a flexible substrate opposite to the rigid transparent substrate is formed on the encapsulating structures. The rigid transparent substrate is cut so as to dispose each of the solar cells respectively on the flexible substrate.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional view illustrating a flexible solar cell according to a first exemplary embodiment.

FIG. 2 is a cross-sectional view illustrating a flexible solar cell according to a second exemplary embodiment.

FIG. 3A through FIG. 9 are manufacturing flowchart diagrams illustrating a flexible solar cell according to a third exemplary embodiment. FIG. 3A, FIG. 4A and FIG. 5A are top views; FIG. 3B, FIG. 4B and FIG. 5B are cross-sectional views taken along lines B-B of FIG. 3A, FIG. 4A and FIG. 5A, respectively; FIG. 6 through FIG. 9 are cross-sectional views illustrating a manufacturing process following FIG. 5B.

FIG. 10 through FIG. 13 are cross-sectional views illustrating another manufacturing process according to the third exemplary embodiment.

FIG. 14 through FIG. 17 are cross-sectional views illustrating yet another manufacturing process according to the third exemplary embodiment.

### DETAILED DESCRIPTION OF DISCLOSED EMBODIMENTS

Several exemplary embodiments are illustrated in the following description to describe the disclosure.

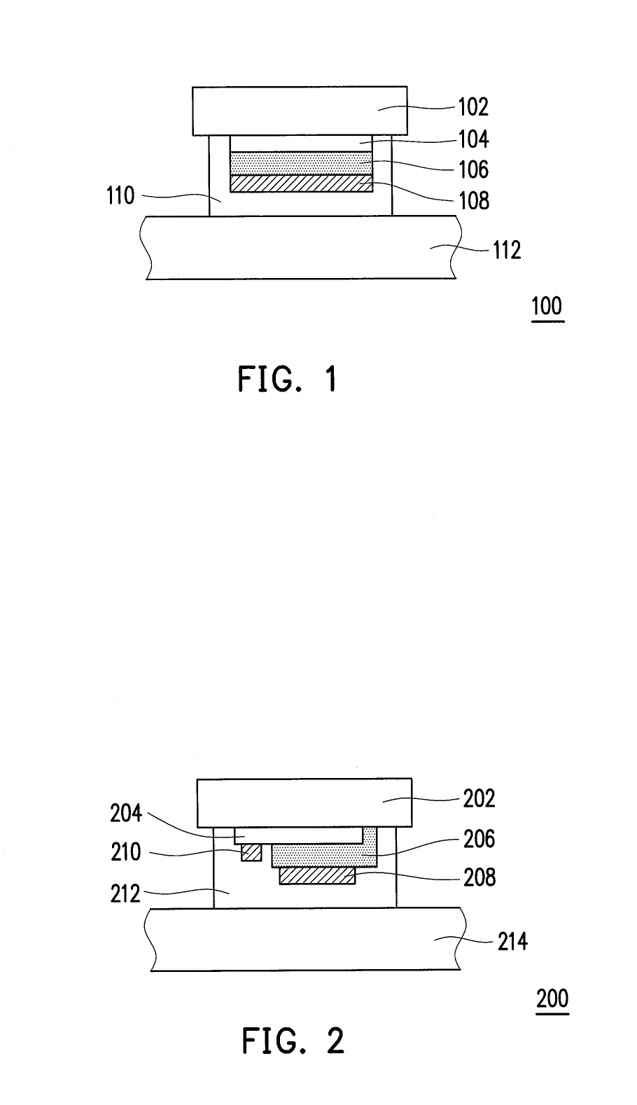

FIG. 1 is a cross-sectional view illustrating a flexible solar cell according to a first exemplary embodiment.

Referring to FIG. 1, the flexible solar cell 100 of the first exemplary embodiment includes a rigid transparent substrate 102, a transparent electrode 104 disposed on the rigid transparent substrate 102, a photoactive layer 106 disposed on the transparent electrode 104, a metal electrode 108 disposed on the photoactive layer 106, an encapsulating structure 110 sealing the transparent electrode 104, the photoactive layer 106 and the metal electrode 108 on the rigid transparent substrate 102, and a flexible substrate 112 opposite to the rigid transparent substrate 102 disposed on the encapsulating structure 110. In the first exemplary embodiment, the photoactive layer 106 and the rigid transparent substrate 102 are separated form each other through the transparent electrode 104. The encapsulating structure 110 shown in the exemplary embodiment is an encapsulant, but the disclosure is not limited thereto. It may also be in other types such as a type having an encapsulating support and an encapsulating cover. The flexible substrate 112 includes a metal substrate or a plastic substrate. For example, when the metal substrate is utilized as the flexible substrate 112 and the glass substrate is utilized as the rigid transparent substrate 102, such design is capable of resisting moisture and oxygen.

FIG. 2 is a cross-sectional view illustrating a flexible solar cell according to a second exemplary embodiment.

Referring to FIG. 2, the flexible solar cell 200 of the second exemplary embodiment includes a rigid transparent substrate 202, a transparent electrode 204 disposed on the rigid transparent substrate 202, a photoactive layer 206 disposed on the transparent electrode 204, a metal electrode 208 disposed on the photoactive layer 206, a metal layer 210, an encapsulating structure 212, and a flexible substrate 214 opposite to the rigid transparent substrate 202 disposed on the encapsulating structure 212. The transparent electrode 204, the photoactive layer 206, the metal electrode 208 and the metal layer 210 are sealed by the encapsulating structure 212 on the rigid transparent substrate 202. A portion of the photoactive layer 206 covers the transparent electrode 204, and thus the transparent electrode 204 is exposed partially. A portion of the photoactive layer 206 is contacted with the rigid transparent substrate 202. The metal layer 210 is disposed on the exposed portion of the transparent electrode 204, and the metal layer 210 is electrically isolated from the metal electrode 208, for example. The encapsulating structure 212 in the exemplary embodiment is an encapsulant, but the disclosure is not limited thereto. It may also be made up of an encapsulating support and an encapsulating cover, for instance. The metal layer 210 may be formed simultaneously with the metal electrode 208 and configured to improve the current collection efficiency of the transparent electrode 204. The flexible substrate 214 is the same as the first exemplary embodiment, which may include a metal substrate or a plastic substrate.

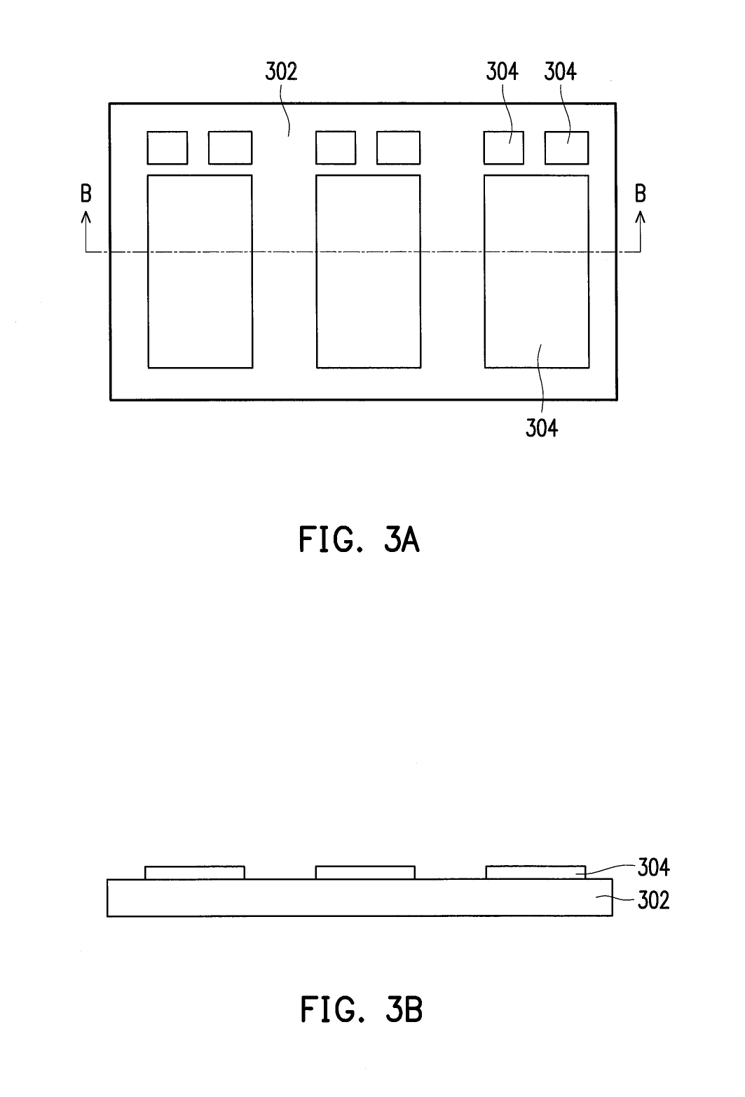

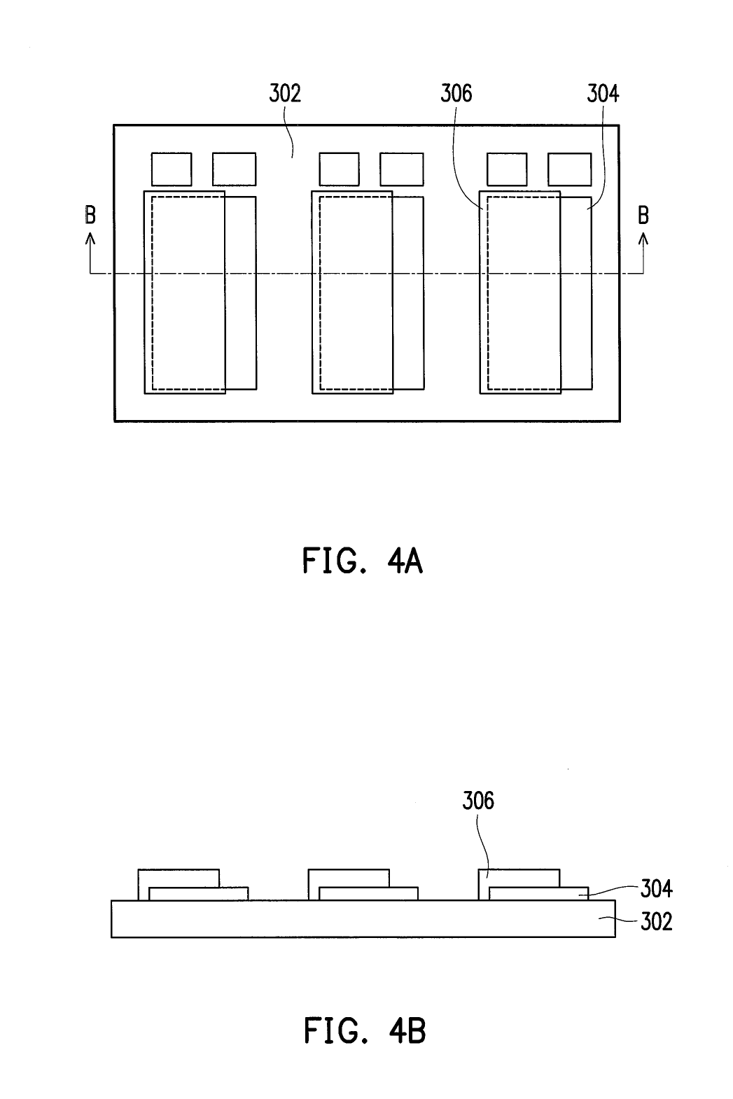

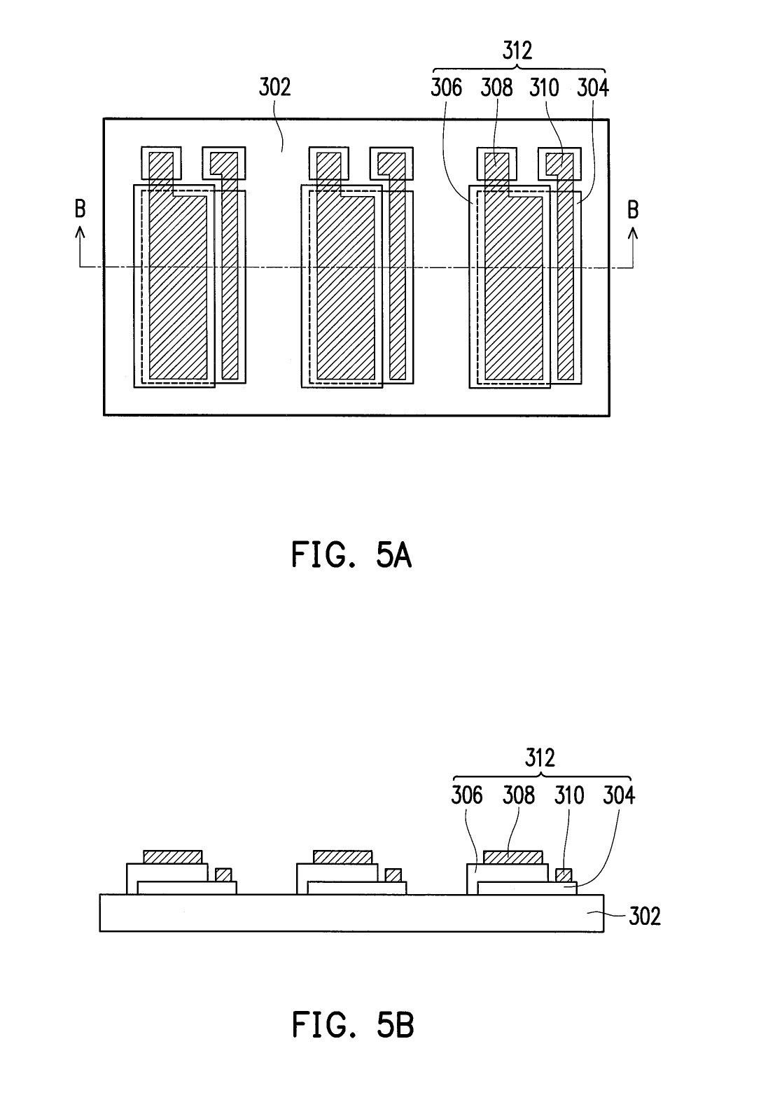

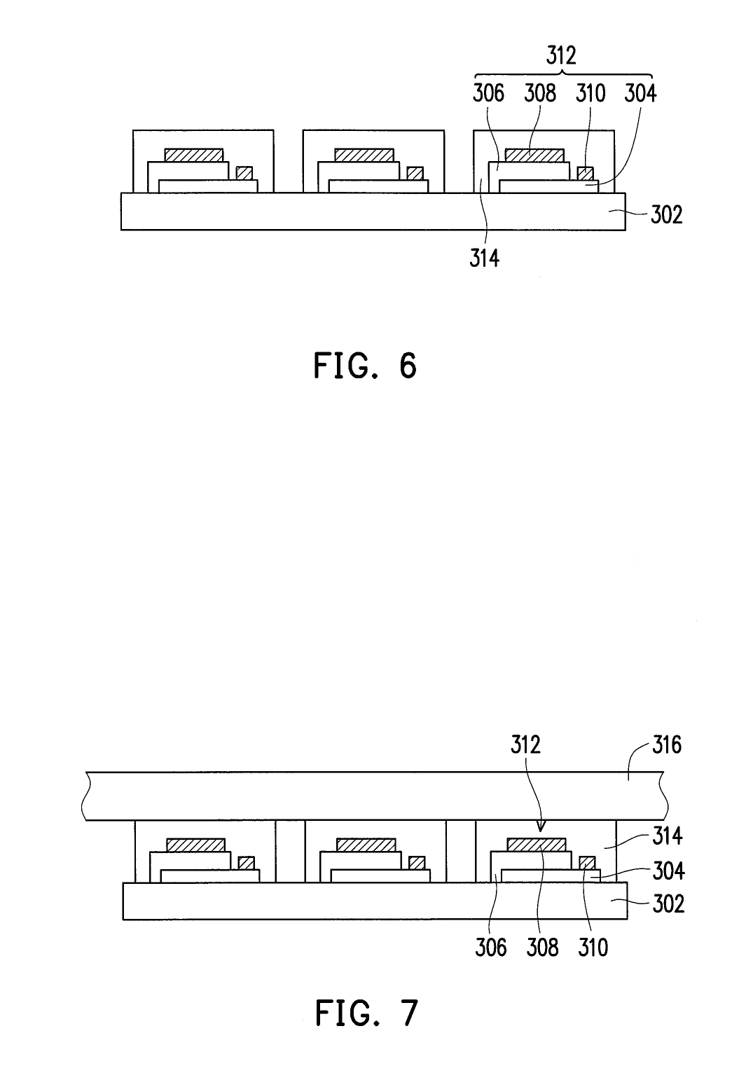

FIG. 3A through FIG. 9 are manufacturing flowchart diagrams illustrating a flexible solar cell according to a third exemplary embodiment. FIG. 3A, FIG. 4A and FIG. 5A are top views; FIG. 3B, FIG. 4B and FIG. 5B are cross-sectional views taken along lines B-B of FIG. 3A, FIG. 4A and FIG. 5A, respectively; and FIG. 6 through FIG. 9 are cross-sectional views illustrating a manufacturing process following FIG. 5B.

Firstly, referring to FIG. 3A and FIG. 3B, a rigid transparent substrate 302 is provided, and a plurality of transparent electrode 304 are formed on the rigid transparent substrate 302. Although three repeated transparent electrodes 304 are exemplified in the exemplary embodiment, the amount and the pattern of the transparent electrode 304 may be modified according to the design requirement. The disclosure is not limited thereto.

Subsequently, referring to FIG. 4A and FIG. 4B, a photoactive layer 306 is formed on each of the transparent electrodes 304. The photoactive layer 306 only partially covers the transparent electrode 304, so as to expose a portion of the transparent electrode 304, and a portion of the photoactive layer 306 may contact with the rigid transparent substrate 302, but the disclosure is not limited thereto. Moreover, for example, the photoactive layer 306 may be formed on the transparent electrode 304 without contacting with the rigid transparent substrate 302.

Thereafter, referring to FIG. 5A and FIG. 5B, the metal electrode 308 and the metal layer 310 are formed on each of the photoactive layers 306, so as to form three solar cells 312 constituted by the transparent electrode 304, the photoactive layer 306 and the metal electrode 308. The metal electrode 308 and the metal layer 310 may be formed simultaneously, wherein the metal layer 310 is electrically isolated form the metal electrode 308. The metal layers 310 may be configured to connect a plurality of solar cells 312 in series or in parallel, such that the solar cells 312 of the exemplary embodiment may be configured to connect in series, in parallel or in series-parallel to form a solar cell module.

Afterwards, referring to FIG. 6, three encapsulating structures 314 are formed on the rigid transparent substrate 302, wherein each of the solar cells 312 are sealed by each of the encapsulating structures 314. The encapsulating structure 314 shown in the exemplary embodiment is an encapsulant, but the disclosure is not limited thereto. For example, the encapsulant is formed by coating a light-curable encapsulating glue around the solar cell 312 and then irradiating ultraviolet (UV) light to cure the glue, in order to achieve the performance of encapsulating. Alternatively, other methods such as evaporation, sputtering or atomic layer deposition may be utilized to cover the solar cell 312 with inorganic metal oxide to achieve the performance of encapsulating.

Thereafter, referring to FIG. 7, the flexible substrate 316 opposite to the rigid transparent substrate 302 is formed on the encapsulating structures 314 by directly using an adhesive material to adhere them, but the disclosure is not limited thereto. The flexible substrate 316 includes a metal substrate or a plastic substrate.

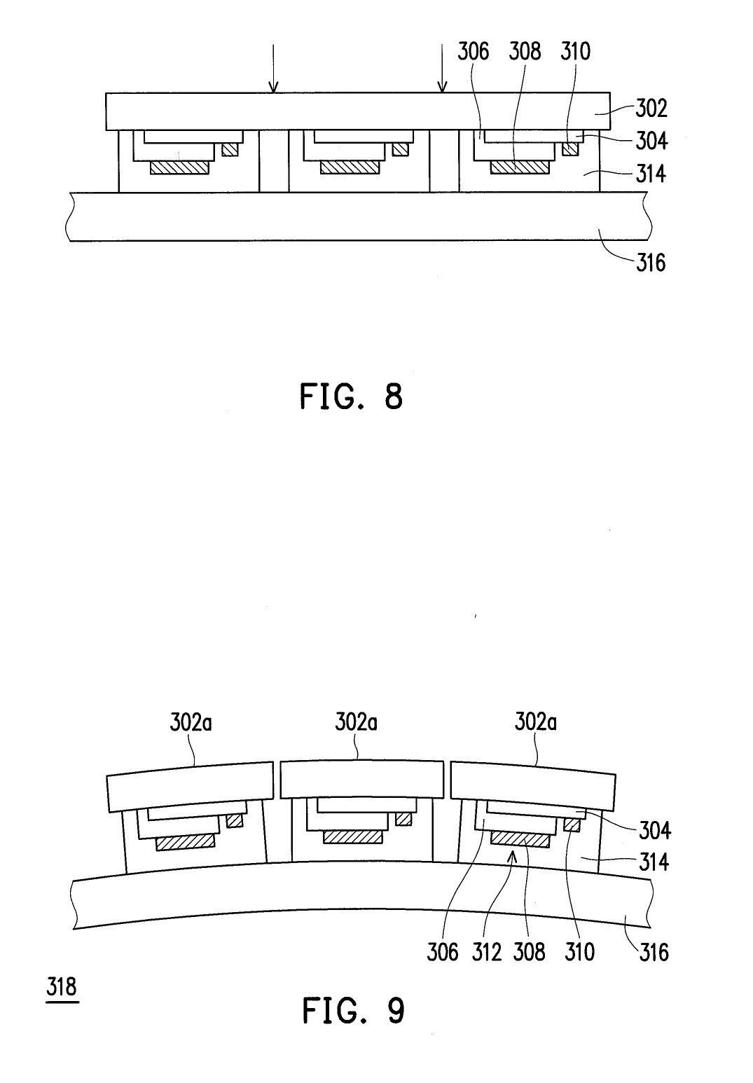

Subsequently, referring to FIG. 8, the structure in FIG. 7 is flipped upside down, and the rigid transparent substrate 302 is cut by mechanical way or laser, but the disclosure is not limited thereto. The cutting locations are illustrated with the arrows in FIG. 8.

Referring to FIG. 9, the cut rigid transparent substrate 302 has turned into three rigid transparent substrates 302a, so that each of the three solar cells 312 is respectively disposed on the flexible substrate 316 to form a flexible solar cell 318 capable of bending.

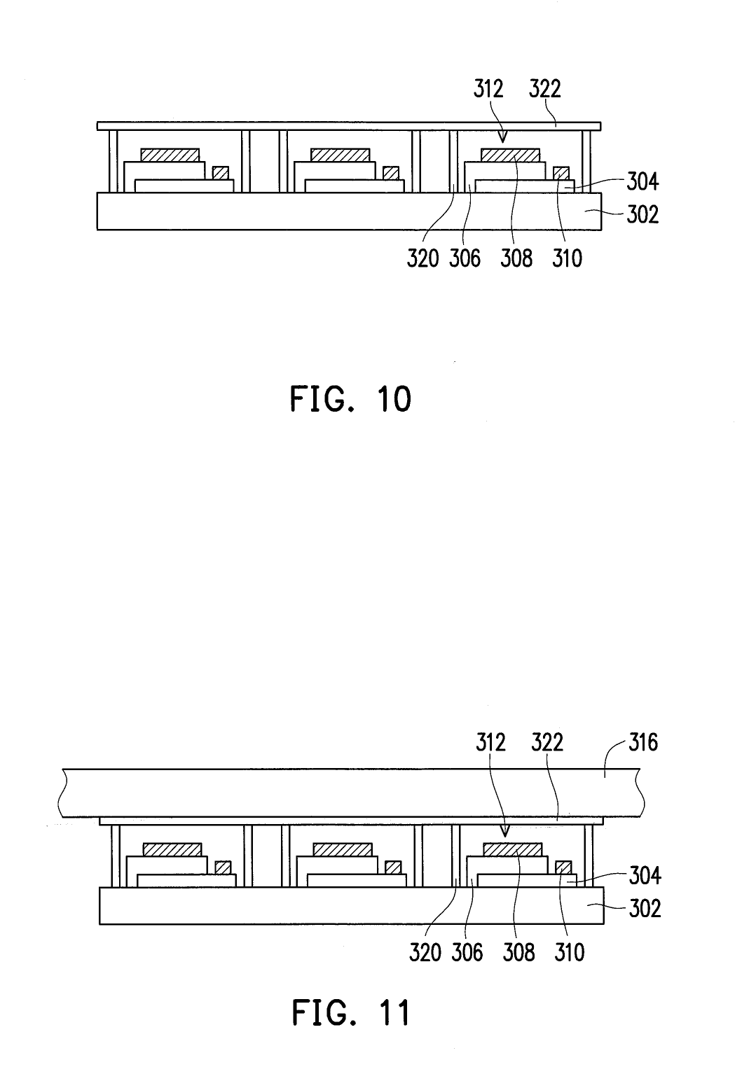

FIG. 10 through FIG. 13 are cross-sectional views illustrating another manufacturing process according to the third exemplary embodiment.

Firstly, the illustrated steps from FIG. 3A through FIG. 5B are performed in the same manner in the third exemplary embodiment. Subsequently, referring to FIG. 10, three encapsulating structures are formed on the rigid transparent substrate 302, wherein each of the encapsulating structures has a detached encapsulating support 320 and a encapsulating cover 322. In the exemplary embodiment, the detached encapsulating supports 320 is formed on the rigid transparent substrate 302 to surround each of the encapsulating supports 320, and then the encapsulating cover 322 is formed on the encapsulating supports 320. For example, a light-curable encapsulating glue is utilized to coat around each the solar cell 312, and then the encapsulating cover 322 is put on the glue followed by irradiating the ultraviolet light to cure the glue.

Thereafter, referring to FIG. 11, the flexible substrate 316 opposite to the rigid transparent substrate 302 is formed on the encapsulating cover 322 by using a adhesive material to adhere them, but the disclosure is not limited thereto.

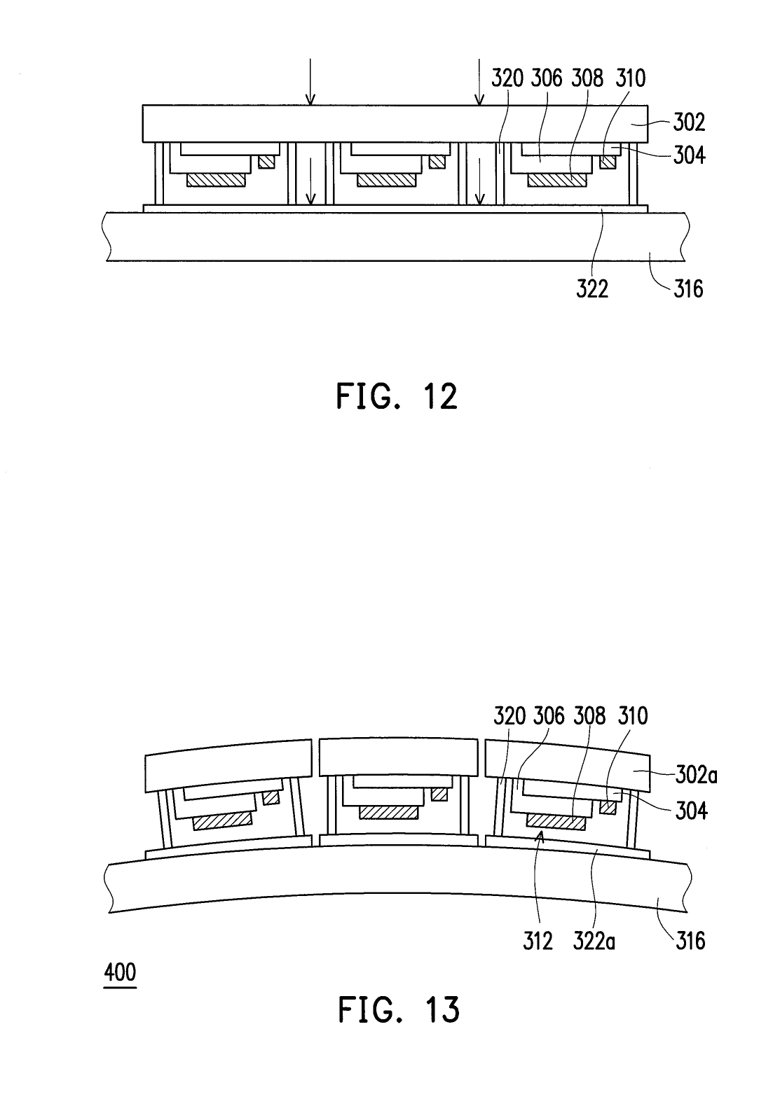

Subsequently, referring to FIG. 12, the structure in FIG. 11 is flipped upside down, and both of the rigid transparent substrate 302 and the encapsulating cover 322 are cut by mechanical way directly or laser, but the disclosure is not limited thereto. The cutting locations are illustrated with the arrows in FIG. 12.

Thereafter, referring to FIG. 13, the cut rigid transparent substrate 302 has turned into three rigid transparent substrates 302a, the cut encapsulating cover 322 has turned into three encapsulating covers 322a, so that the three solar cells 312 are respectively disposed on the flexible substrate 316 to form the flexible solar cell 400 capable of bending.

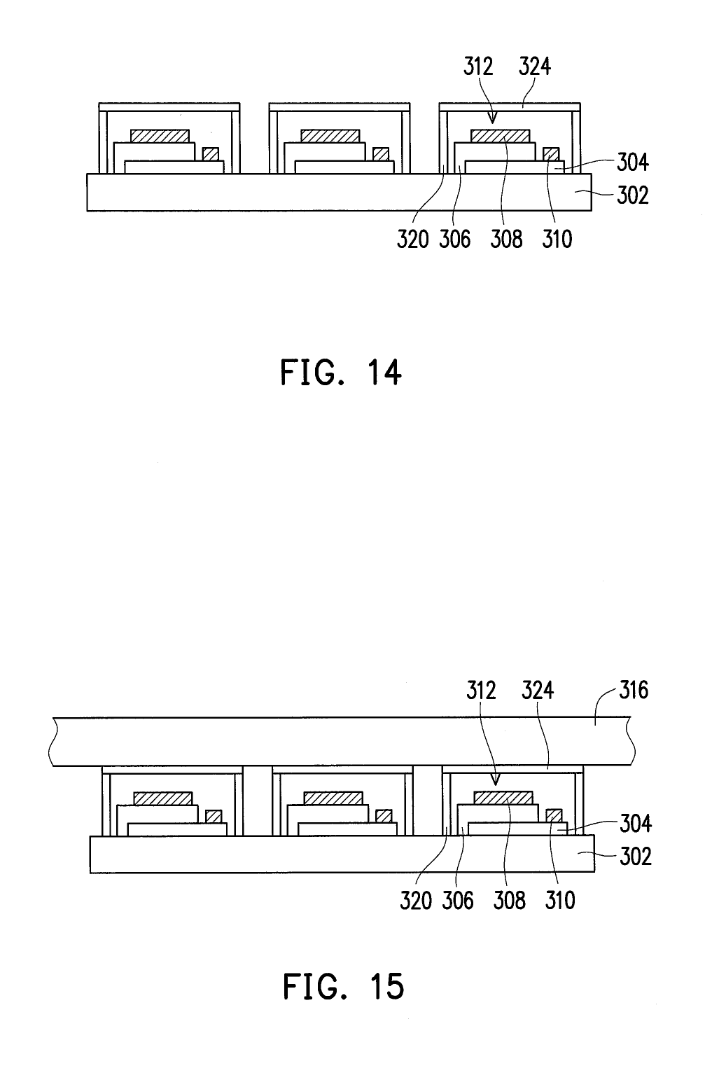

FIG. 14 through FIG. 17 are cross-sectional views illustrating yet another manufacturing process according to the third exemplary embodiment.

Firstly, the illustrated steps from FIG. 3A through FIG. 5B are performed in the same manner in the third exemplary embodiment. Subsequently, referring to FIG. 14, three encapsulating structures are formed on the rigid transparent substrate 302, wherein each of the encapsulating structures includes a detached encapsulating support 320 and a detached encapsulating cover 324. In the exemplary embodiment, the detached encapsulating supports 320 are formed on the rigid transparent substrate 302 to surround each of the solar cells 312, and then the detached encapsulating cover 322 is formed on the encapsulating supports 320. For example, a light-curable encapsulating glue is coated around the solar cell 312, and then the detached encapsulating cover 324 is put on the glue followed by irradiating the ultraviolet light to cure the glue.

Thereafter, referring to FIG. 15, the flexible substrate 316 opposite to the rigid transparent substrate 302 is formed on the detached encapsulating covers 324 by directly using the adhesive materials to adhere them, but the disclosure is not limited thereto.

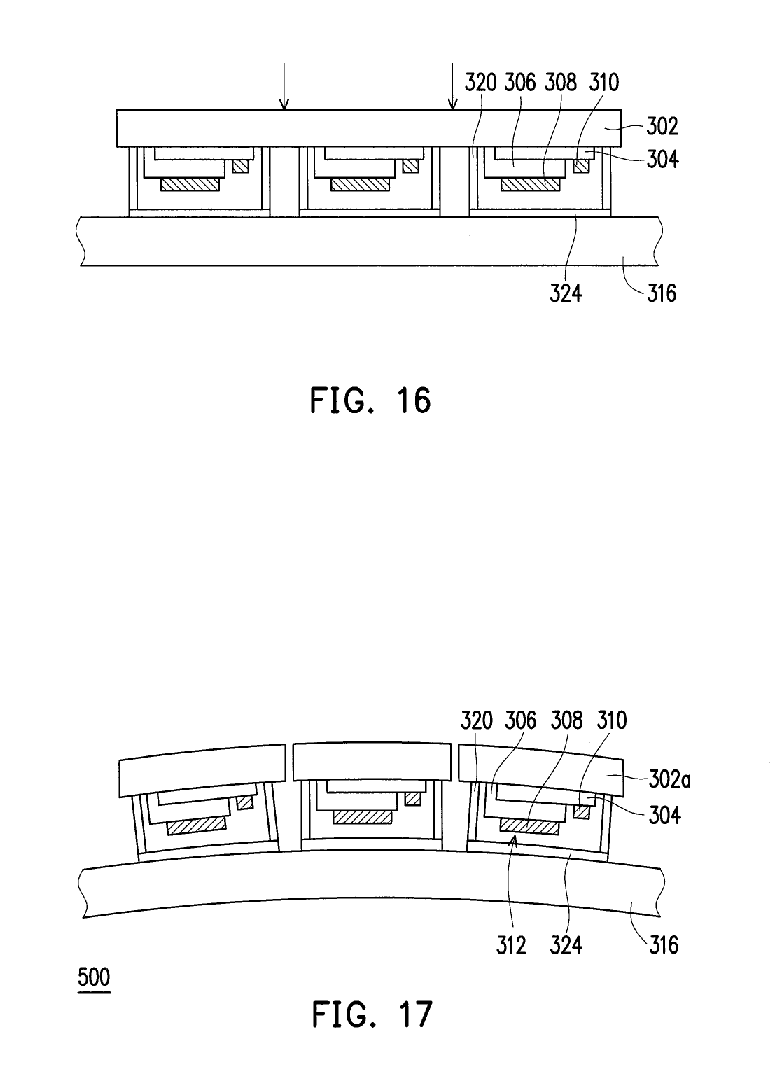

Subsequently, referring to FIG. 16, the structure in FIG. 15 is flipped upside down, and the rigid transparent substrate 302 is cut by a mechanical way or laser, but the disclosure is not limited thereto. The cutting locations are the locations where the arrows are pointed in FIG. 16.

Thereafter, referring to FIG. 17, the cut rigid transparent substrate 302 has turned into three rigid transparent substrates 302a, so that the three solar cells 312 are respectively disposed on the flexible substrate 316 to form the flexible solar cell 500 capable of bending.

Several exemplary examples in the following description demonstrate the disclosure.

### Exemplary Example 1

The flexible solar cell as shown in FIG. 1 is manufactured, wherein the length of the transparent electrode (i.e. indium tin oxide) is 5 cm, and the measured photoelectric conversion efficiency is about 1.25%.

In addition, the flexible solar cell as shown in FIG. 2 is manufactured, wherein the length of the transparent electrode is still 5 cm, but there is a metal layer thereon, and the measured photoelectric conversion efficiency is about 2.6%. Accordingly, the metal layer is capable of improving the current collection efficiency of the transparent electrode.

### Exemplary Example 2

Sixteen flexible solar cell devices shown in FIG. 9 are connected in series, where the total area is 11 cm×11 cm, and the actual operating area for the devices is 72 cm². Under the AM1.5G simulated solar light irradiation with about 44 mW/com² of the light intensity, as presented, the operating voltage (Voc) is 10V, the short-circuit current (Isc) is 24.7 mA, the fill factor is 53.4% and the photoelectric conversion efficiency is 4.16% according to the experimental data, where the operating voltage of a single device is about 0.67V.

To sum up, the transparent electrode, the photoactive layer, the metal electrode and other devices of the flexible solar cell in the disclosure are built on the rigid transparent substrate, therefore, the deterioration of flexible solar cell due to the bending of the solar cell may not occur. In addition, the current collection efficiency of the transparent electrode may be further improved if the metal layer is disposed on the transparent electrode.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

1. A flexible solar cell, comprising:
a rigid transparent substrate;
a transparent electrode, disposed on the rigid transparent substrate;
a photoactive layer, disposed on the transparent electrode;
a metal electrode, disposed on photoactive layer;
an encapsulating structure, sealing the transparent electrode, the photoactive layer and the metal electrode on the rigid transparent substrate; and
a flexible substrate opposite to the rigid transparent substrate, disposed on the encapsulating structure.

2. The flexible solar cell as claimed in claim 1, wherein the photoactive layer and the rigid transparent substrate are insulated from each other through the transparent electrode.

3. The flexible solar cell as claimed in claim 1, wherein the photoactive layer covers a portion of the transparent electrode and the transparent electrode is partially exposed.

4. The flexible solar cell as claimed in claim 1, wherein a portion of the photoactive layer is contacted with the rigid transparent substrate.

5. The flexible solar cell as claimed in claim 3, further comprising a metal layer disposed on the exposed transparent electrode, wherein the metal layer is electrically isolated from the metal electrode.

6. The flexible solar cell as claimed in claim 5, wherein the metal layer is configured to connect a plurality of the flexible solar cells in series or in parallel.

7. The flexible solar cell as claimed in claim 6, wherein the flexible solar cell is configured to connect in series, in parallel or in series-parallel to form a solar cell module.

8. The flexible solar cell as claimed in claim 1, wherein the encapsulating structure comprises an encapsulant or is made up of an encapsulating support and an encapsulating cover.

9. The flexible solar cell as claimed in claim 1, wherein the flexible substrate comprises a metal substrate or a plastic substrate.

10. A manufacturing method of a flexible solar cell, comprising:
providing a rigid transparent substrate;
forming a plurality of transparent electrodes on the rigid transparent substrate;
forming a photoactive layer on each of the transparent electrodes;
forming a metal electrode on the photoactive layer to form a plurality of solar cells constituted by each of the transparent electrodes, the photoactive layer and the metal electrode;
forming a plurality of encapsulating structures on the rigid transparent substrate, wherein each of the solar cells is sealed by each of the encapsulating structures;
forming a flexible substrate opposite to the rigid transparent substrate on the encapsulating structures; and
cutting the rigid transparent substrate so as to dispose each of the solar cells respectively on the flexible substrate.

11. The manufacturing method of the flexible solar cell as claimed in claim 10, wherein the step of forming the photoactive layer comprises: contacting a portion of the photoactive layer with the rigid transparent substrate.

12. The manufacturing method of the flexible solar cell as claimed in claim 10, wherein the step of forming the photoactive layer comprises: insulating the photoactive layer and the rigid transparent substrate from each other through the transparent electrode.

13. The manufacturing method of the flexible solar cell as claimed in claim 10, wherein the step of forming the photoactive layer comprises: exposing a portion of the transparent electrode.

14. The manufacturing method of the flexible solar cell as claimed in claim 13, wherein the step of forming the metal electrode comprises: forming a metal layer on each of the exposed transparent electrodes simultaneously, wherein the metal layer is electrically isolated from the metal electrode.

15. The manufacturing method of the flexible solar cell as claimed in claim 10, wherein the encapsulating structures comprise an encapsulant, or each of the encapsulating structures is made up of an encapsulating support and an encapsulating cover.

16. The manufacturing method of the flexible solar cell as claimed in claim 15, wherein the encapsulating support in each of the encapsulating structures is detached.

17. The manufacturing method of the flexible solar cell as claimed in claim 16, wherein the step of forming the plurality of encapsulating structures comprises:
forming a plurality of the detached encapsulating supports on the rigid transparent substrate, where each of the detached encapsulating supports surrounds each of the solar cells; and
forming the encapsulating cover on the detached encapsulating supports.

18. The manufacturing method of the flexible solar cell as claimed in claim 17, wherein the step of cutting the rigid transparent substrate further comprises: cutting the encapsulating cover so as to dispose each of the solar cells respectively on the flexible substrate.

19. The manufacturing method of the flexible solar cell as claimed in claim 15, wherein the encapsulating support and the encapsulating cover in each of the encapsulating structures are detached.

20. The manufacturing method of the flexible solar cell as claimed in claim 19, wherein the step of forming the plurality of encapsulating structures comprises:
forming a plurality of the detached encapsulating supports on the rigid transparent substrate, where each of the encapsulating supports surrounds each of the solar cells; and
forming a plurality of the detached encapsulating covers on each of the detached encapsulating supports.
